(19) United States
(12) Patent Application Publication
(10) Pub. No.: US 2014/0001933 A1
(43) Pub. Date: Jan. 2, 2014

(54) CHASSIS OF ELECTRONIC DEVICE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/553,318

(22) Filed: Jul. 19, 2012

(30) Foreign Application Priority Data
Jun. 28, 2012 (CN) 2012102176625

(51) Int. Cl. H05K 5/02

(52) U.S. Cl. 312/223.1

(57) ABSTRACT

A chassis of an electronic device includes an enclosure and a number of ball bars each having a number of balls. The enclosure defines a number of through holes. The ball bars are installed to an inner surface of the enclosure so the balls are rotatably received in the through holes. A lower part of each ball extends out of a bottom surface of the enclosure through the through hole.

### BACKGROUND

1. Technical Field

The disclosure relates to a chassis of an electronic device.

2. Description of Related Art

A chassis of an electronic device, such as a server, may be equipped with a plurality of support feet mounted on a bottom wall of the chassis. The support feet often stand directly on a supporting surface. However, such support feet render it inconvenient and difficult to carry the chassis.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a chassis.

FIG. 2 is an assembled, isometric view of the chassis of FIG. 1.

FIG. 3 is a cross-sectional view of the objects in FIG. 2, taken along the line of III-III.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

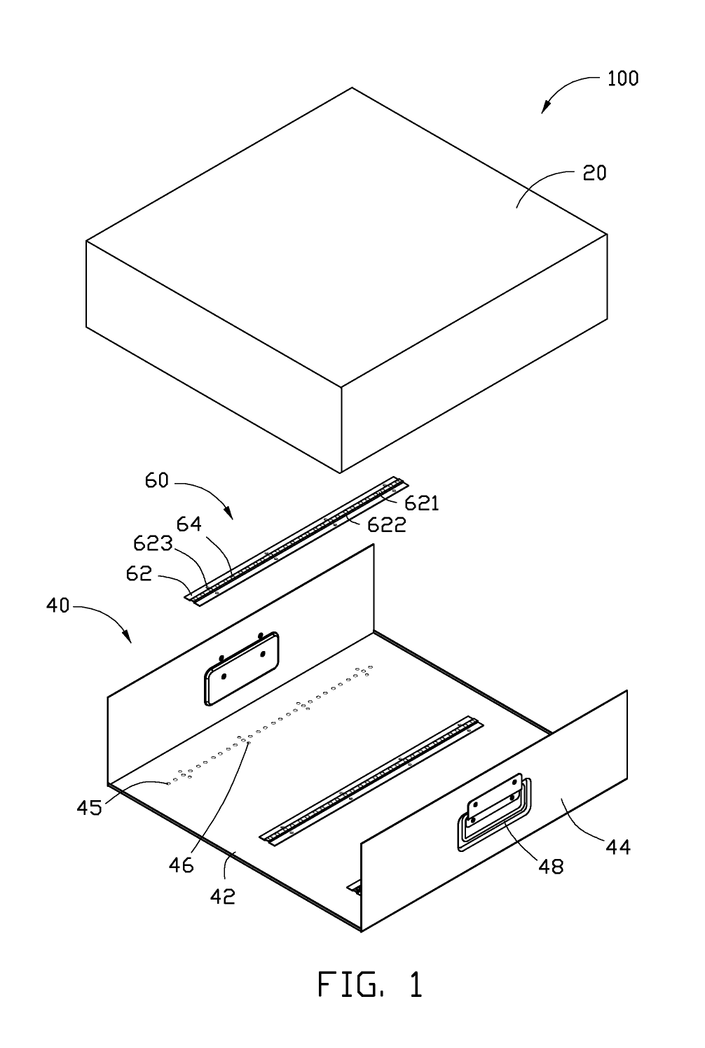

Referring to FIG. 1, an exemplary embodiment of a chassis 100 of an electronic device includes a main body 20, an enclosure 40, and three ball bars 60. In the embodiment, the electronic device is a server, and the main body 20 houses a motherboard, a power supply, a plurality of hard disk drives, and other functioning modules (not shown).

The enclosure 40 includes a support wall 42 and two sidewalls 44 extending up from opposite sides of the support wall 42. The support wall 42 defines three rows of spaced through holes 45. Each row of through holes 45 is parallel to the sidewalls 44. A number of screw holes 46 in the support wall 42 flank each row of through holes 45. A handle 48 is formed on an outer surface of each sidewall 44.

Each ball bar 60 includes a bar-shaped bracket 62, and a row of balls 64. A receiving portion 621 is raised up from a middle of the bracket 62 along a lengthwise direction. The receiving portion 621 defines a row of receiving holes 622 along a lengthwise direction of the receiving portion 621 for rotatably receiving the balls 64. The bracket 62 defines a plurality of positioning holes 623 therein, at opposite sides of the receiving portion 621.

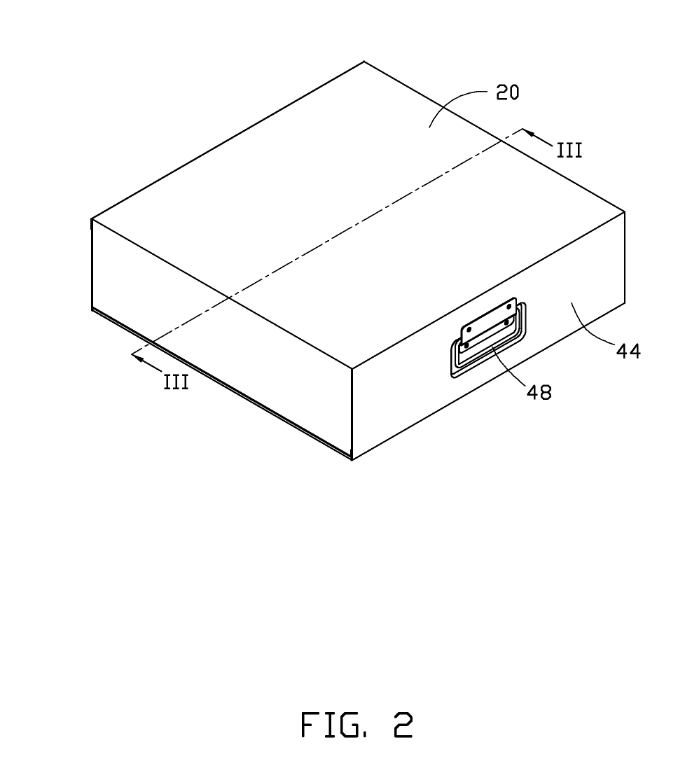

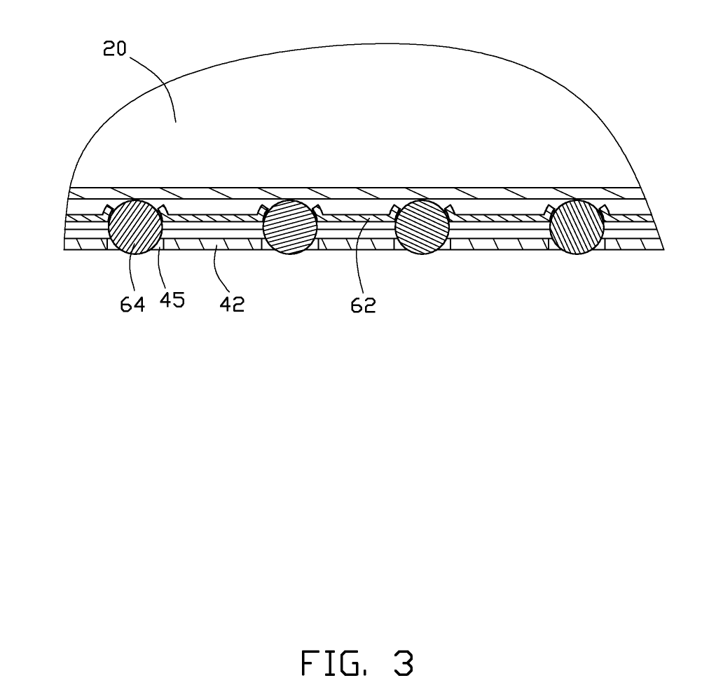

Referring to FIG. 2 and FIG. 3, in assembly, the ball bars 60 are supported on an inner surface of the support wall 42, above the rows of through holes 45. The balls 64 are rotatably received in the through holes 45. A screw extends through each positioning hole 623 of the ball bars 60, to be screwed into the screw holes 46 of the support wall 42. The main body 20 is installed in the enclosure 40 by screwing or clamping. A lower part of each ball 64 extends extended out of the bottom of the support wall 42 through the through hole 45.

The chassis 100 can be easily moved, because of the balls 64, and expediently carried or pulled by the handles 48.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A chassis, comprising:
an enclosure comprising a support wall, and the support wall defining a plurality of through holes; and
a ball bar, installed on an inner surface of the support wall, comprising a plurality of balls rotatably extending through the corresponding through holes, wherein lower portions of the balls are extended out of a bottom surface of the support wall through the corresponding through holes.

2. The chassis of claim 1, wherein the enclosure further comprises two sidewalls extending up from two opposite sides of the support wall, a handle is formed on an outer surface of each sidewall.

3. The chassis of claim 2, wherein the ball bar comprises a bar-shaped bracket supported on the inner surface of the support wall, the plurality of balls are rotatably installed to the bar-shaped bracket.

4. The chassis of claim 3, wherein the bar-shaped bracket comprises a raised receiving portion extending up from the bar-shaped bracket along a lengthwise direction of the bar-shaped bracket, and the raised receiving portion defines a plurality of receiving holes along a lengthwise direction of the raised receiving portion for rotatably receiving the plurality of balls.
